(19) United States
(12) Patent Application Publication
(10) Pub. No.: US 2025/0140108 A1
(43) Pub. Date: May 1, 2025

(54) TEST METHOD FOR VARIABLE SPEED LIMIT STRATEGY IN MIXED TRAFFIC FLOW CONSIDERING DRIVER COMPLIANCE

(71) Applicant: CHANG'AN UNIVERSITY, Xi'an (CN)

(72) Inventors: Siyuan GONG, Xi'an (CN); Jiawei LU, Xi'an (CN); Xia WU, Xi'an (CN); Xinyi LI, Xi'an (CN); Wenjing WANG, Xi'an (CN); Yukun DING, Xi'an (CN); Yan WANG, Xi'an (CN); Jiadong LI, Xi'an (CN); Guohui ZHENG, Xi'an (CN); Dengrong LI, Xi'an (CN); Ze LI, Xi'an (CN); Jingjie XIA, Xi'an (CN); Shanzheng XUE, Xi'an (CN)

(21) Appl. No.: 19/007,041

(22) Filed: Dec. 31, 2024

(30) Foreign Application Priority Data
Mar. 11, 2024 (CN) 202410274352.X

(51) Int. Cl. G08G 1/01; G08G 1/052

(52) U.S. Cl. CPC G08G 1/0145; G08G 1/0133; G08G 1/052

(57) ABSTRACT

A test method for a variable speed limit (VSL) strategy in a mixed traffic flow considering driver compliance is provided. A road scenario is built, and multiple mixed traffic flows formed by human-driven vehicles (HDVs) and connected and automated vehicles (CAVs) are set, which vary in CAV penetration rate. The VSL strategy is established, and a speed limit of an upstream of the bottleneck area is calculated based on the VSL strategy. A HDV compliance is established, and in combination with the speed limit, the HDV drivers are classified, and a proportion of the HDV drivers in individual types in the road scenario is determined. Based on a traffic flow scenario in which the HDV drivers and CAV drivers are located, indicator data reflecting traffic capacity is calculated. A test system for performing the test method is further provided.

### CROSS-REFERENCE TO RELATED APPLICATIONS

This application claims the benefit of priority from Chinese Patent Application No. 202410274352.X, filed on Mar. 11, 2024. The content of the aforementioned application, including any intervening amendments thereto, is incorporated herein by reference in its entirety.

### TECHNICAL FIELD

This application relates to intelligent traffic control, and more particularly to a test method for a variable speed limit (VSL) strategy in a mixed traffic flow considering driver compliance.

### BACKGROUND

When the traffic is in a state that the demand exceeds the supply, any slight disturbance will easily cause traffic oscillation and its propagation, which will further lead to traffic congestion and affect the capacity of the transportation system. As an effective highway traffic control method, the variable speed limit control technology has received considerable attention from domestic and foreign traffic managers.

The control effect of the variable speed limit technology depends greatly on the adopted control strategy. Since the variable speed limit control strategy is essentially demand-responsive and heuristic, the control effect of the variable speed limit strategy is dependent on the driver compliance. Moreover, with the continuous development of connected and automated vehicles (CAVs), mixed traffic flows appear. In the mixed traffic flows, human drivers will be affected by the strict compliance of the CAVs to the speed limit, and the compliance characteristics will be different from the driving environment of human drivers. Moreover, this phenomenon will exist in the real scenario for a long time, so it is necessary to consider the fusion of the driver's compliance and the penetration rate of CAVs in the construction and test of VSL strategies.

Currently, the researches on variable speed limit strategies mainly focus on the theoretical level. Though some researches have involved the mixed traffic flow and the construction of simulation scenarios with different penetration rates of CAVs, these researches only mention that the CAVs will rely on precise sensing, passing and controlling abilities to strictly comply with the speed limit on the VSL signs, and these researches fail to consider the response of vehicles other than CAVs (e.g., traditional human-driven vehicles) to the speed limit, which makes the testing of VSL strategy difficult to be applied to the practical traffic conditions.

### SUMMARY

In view of the deficiencies in the prior art that the existing speed limit strategies have a poor test accuracy because the reaction of traditional human-driven vehicles to the speed limit is not considered, this application provides a test method for a variable speed limit strategy in a mixed traffic flow that considers the driver compliance.

Technical solutions of this application are described as follows.

This application provides a test method for a variable speed limit (VSL) strategy in a mixed traffic flow considering driver compliance, comprising:
(1) building a road scenario based on a road condition of a bottleneck area formed by a main road and an on-ramp, wherein the main road is a three-lane road, and the on-ramp is a single-lane road; and setting a plurality of mixed traffic flows respectively consisting of human-driven vehicles (HDVs) and connected and automated vehicles (CAVs), wherein the plurality of mixed traffic flows vary in CAV penetration rate;
(2) establishing the VSL strategy; and for each of the plurality of mixed traffic flows, calculating a speed limit at an upstream of the bottleneck area based on the VSL strategy;
(3) establishing a HDV compliance; and based on the HDV compliance in combination with the speed limit, classifying HDV drivers in the road scenario, and determining a proportion of the HDV drivers in individual types; and
(4) determining a traffic flow scenario in which the HDV drivers and CAV drivers are located, and testing the traffic flow scenario to obtain indicator data reflecting traffic capacity.

In an embodiment, the number of the plurality of mixed traffic flows is five, and five mixed traffic flows are 100% HDV, 90% HDV-10% CAV, 80% HDV-20% CAV, 70% HDV-30% CAV, and 10% HDV-90% CAV, respectively; and the HDVs are the same as the CAVs in length and width.

In an embodiment, the VSL strategy comprises a feedback-based VSL strategy and an optimization-based VSL control strategy.

In an embodiment, the feedback-based VSL strategy comprises a two-stage cascade feedback control; a first-stage control of the two-stage cascade feedback control is configured to adjust a target flow volume to approach a target density in the bottleneck area, so as to maximize a flow volume in the bottleneck area; and a second-stage control of the two-stage cascade feedback control is configured to adjust a ratio of the speed limit to a free flow velocity to regulate an outflow of a variable speed limit control area.

In an embodiment, the speed limit is determined based on the optimization-based VSL control strategy through steps of:
(S11) building an analytical model based on a cell transmission model; and dividing a highway into variable length regions with a cell length of Δx, and dividing time into discrete time steps with a duration time of Δt; wherein a length Δxᵢ of each cell follows a constraint of modeling step, and v_{free}Δt≤Δxᵢ, where v_{free} represents the free flow velocity;
(S12) modeling the bottleneck area, and modifying the free flow velocity to modify a traffic fundamental diagram, so as to adjust the flow volume in the bottleneck area; and
(S13) according to a modified traffic fundamental diagram obtained in step (S12), analyzing a density dynamic and a velocity dynamic to obtain a cell density and a cell average velocity; wherein for a cell to which the optimization-based VSL control strategy is applied, the cell average velocity is predicted through the following formula:

$${v}_{i} ( k + 1 ) = {r}_{c a v} * {u}_{i} ( k ) + ( 1 - {r}_{c a v} ) * [ {r}_{d e} * ( {u}_{i} ( k ) - 5 ) + {r}_{c o} * {u}_{i} ( k ) + {r}_{a g} * ( {u}_{i} ( k ) + 5 ) ] ;$$

wherein uᵢ(k) denotes a speed limit of a (k+1)-th step predicted at a k-th step; r_{cav} denotes a proportion of CAVs in a traffic flow; and r_{de}, r_{co}, and r_{ag} represents proportions of defensive drivers, compliant drivers, and aggressive drivers, respectively.

In an embodiment, the speed limit is 40, 50, 60, 70, 80, 90, 100 or 110 km/h; and
the HDV drivers are classified into the defensive drivers, the aggressive drivers, and the compliant drivers based on a travelling speed; the defensive drivers travel at a speed equal to or below (the speed limit−5) km/h; the aggressive drivers travel at a speed equal to or above (the speed limit+5) km/h; and the compliant drivers travel at a speed within a range of (the speed limit±5) km/h.

In an embodiment, the HDV compliance represents a compliance of a HDV in a current traffic condition to a speed limit, and a proportion of the compliant drivers in the HDV drivers; and the HDV compliance comprises a low-level compliance, a medium-level compliance, a high-level compliance, and an ideal-level compliance, wherein the low-level compliance indicates that the proportion of the compliant drivers is 20%, the medium-level compliance indicates that the proportion of the compliant drivers is 45%, the high-level compliance indicates that the proportion of the compliant drivers is 80%, and the ideal-level compliance indicates that the proportion of the compliant drivers is 100%.

This application further provides a system for implementing the test method above, comprising:
a first building module;
a VSL strategy module;
a second building module;
an acquisition module; and
a data processing module;
wherein the first building module is configured to build the road scenario; the VSL strategy module is configured to build the VSL strategy; the second building module is configured to establish the HDV compliance; the acquisition module is configured to obtain CAV penetration rates; and the data processing module is configured to calculate a speed limit of the bottleneck area, classify the HDV drivers, determine the proportion of the HDV drivers in individual types, and obtain the indicator data reflecting the traffic capacity.

This application further provides a terminal device, comprising:
a memory;
a processor; and
a computer program;
wherein the computer program is stored in the memory, and is configured to be operated on the processor; and the processor is configured to execute the computer program to implement the test method above.

This application further provides a non-transitory computer-readable storage medium, wherein a computer program is stored on the non-transitory computer-readable storage medium; and the computer program is configured to be executed by a processor to implement the test method above.

Compared to the prior art, this application has the following beneficial effects.

A test method provided herein for a VSL strategy in a mixed traffic flow considering driver compliance builds a mixed traffic flow scenario with the penetration rate of CAVs based on the microscopic simulation software and related research. The test method analyzes “real-world” data to determine four compliance scenarios and the proportion of defensive drivers and aggressive drivers in response to different speed limits under the corresponding compliance scenarios. Therefore, the test method provides a speed limit strategy for the CAVs and traditional human-driven vehicles. In the test method, the mixed traffic flow scenario is closer to the real road scenarios, thereby improving the testing accuracy of the VSL strategy, and showing more practical significance for the testing effect of the VSL strategy. Furthermore, the test method can lay the foundation for constructing the VSL strategy considering the penetration rate of CAVs and the compliance of the HDV driver.

In the process of obtaining the speed limit based on the optimization-based VSL control strategy, the cell density evolution and the cell velocity evolution are calculated by modeling the cell transmission model, so as to obtain the optimal value of the objective function to determine the speed limit. Specifically, each cell has a separate demand function and a separate supply function, which can correspond to the modification of the free flow velocity and the modeling of bottleneck areas for the traffic fundamental diagram. When the bottleneck area is activated, the capacity will drop. After the demand function and the supply function of the cell have been determined, the individual cell flows are computed to predict the cell density evolution.

Further, the objective function consisting of a weighted sum of the total travel time and the total travel distance is calculated based the density prediction and the average velocity prediction. Therefore, the speed limit for the next stage can be determined when the current speed limit is determined and constrained by each realistic specification, so the speed limits in the two steps can be predicted, thereby selecting the speed limit that makes the objective function optimal.

### BRIEF DESCRIPTION OF THE DRAWINGS

FIG. 1 is a flow diagram of a test method for a variable speed limit (VSL) strategy in a mixed traffic flow considering driver compliance according to an embodiment of the present disclosure;

FIG. 2 is a three-dimensional diagram of a road scenario according to an embodiment of the present disclosure;

FIG. 3 is a technical flow diagram of a test system according to an embodiment of the present disclosure;

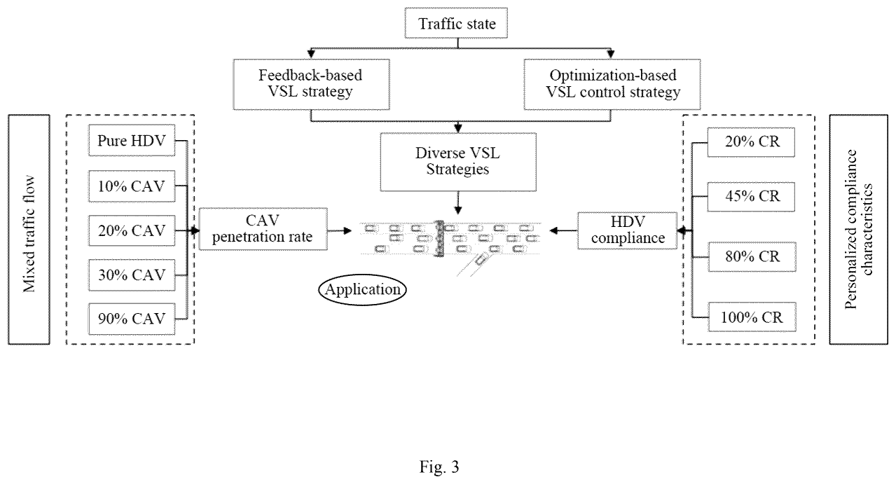

FIG. 4 is a schematic diagram of a localized feedback controller according to an embodiment of the present disclosure;

FIG. 5a shows a traffic fundamental diagram of a cell not controlled by the optimization-based VSL control strategy;

FIG. 5b shows a traffic fundamental diagram of a cell controlled by the optimization-based VSL control strategy;

FIG. 5c shows a traffic fundamental diagram when a capacity of the bottleneck area decreases;

FIG. 6 is vehicles volume under a feedback-based VSL strategy;

FIG. 7 is vehicles volume under an optimization-based VSL control strategy;

FIG. 8 shows average travel time of vehicles within 1 km upstream of a bottleneck area under the feedback-based VSL strategy;

FIG. 9 shows average travel time of vehicles within 1 km upstream of the bottleneck area under the optimization-based VSL control strategy;

FIG. 10 shows average delay of vehicles under the feedback-based VSL strategy;

FIG. 11 shows average delay of vehicles under the optimization-based VSL control strategy;

FIG. 12 shows average fuel consumption of vehicles under the feedback-based VSL strategy;

FIG. 13 shows average fuel consumption of vehicles under the optimization-based VSL control strategy;

FIG. 14 shows total CO emission under the feedback-based VSL strategy;

FIG. 15 shows total CO emission under the optimization-based VSL control strategy;

FIG. 16 shows total VOC emission under the feedback-based VSL strategy;

FIG. 17 shows total VOC emission under the optimization-based VSL control strategy; and

FIG. 18 is an interface of a test system for a VSL strategy in a mixed traffic flow considering driver compliance according to an embodiment of the present disclosure.

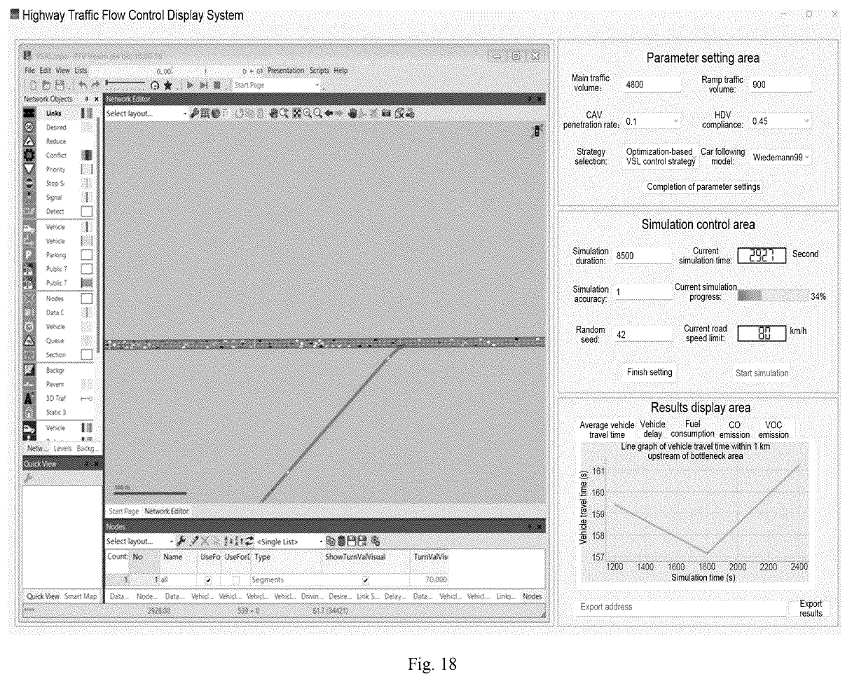

### DETAILED DESCRIPTION OF EMBODIMENTS

The present disclosure will be further described in detail below in connection with the accompanying drawings and embodiments, which are only for explanation purposes and are not intended to limit the disclosure.

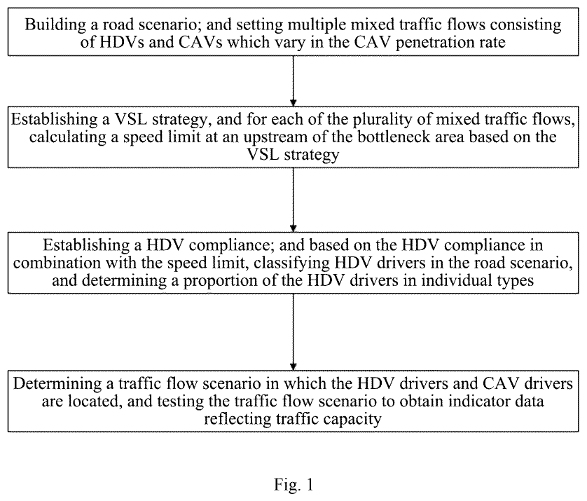

Referring to FIG. 1, a test method for a variable speed limit (VSL) strategy in a mixed traffic flow considering driver compliance provided in this disclosure includes the following steps.

The road scenario is built based on the road condition of a bottleneck area formed by a main road and an on-ramp, where the main road is a three-lane road, and the on-ramp is a single-lane road. A plurality of mixed traffic flows respectively consisting of human-driven vehicles (HDVs) and connected and automated vehicles (CAVs) are set, and a plurality of mixed traffic flows vary in CAV penetration rates.

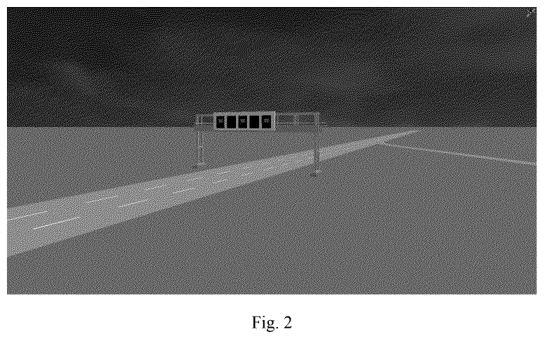

Specifically, the road scenario is built based on the Verkehr In Städten—SIMulationsmodell (VISSIM) highway simulation platform, as shown in FIG. 2. Through reading a lot of literature, it can be found that the VSL control technology is mostly applied to the dispersion of traffic flow in the bottleneck area. The formation of bottleneck area is caused by many factors, such as road repair, traffic accidents, and weather conditions. But in the final analysis, the bottleneck area is all caused by actual road traffic volume being higher than the capacity of the road. For many uncontrollable factors, the road scenario takes the three-lane road as the main road and the single-lane road as the on-ramp, and selects the road condition where the main road and the on-ramp converge to form the bottleneck area. The road scenarios with different CAV penetration ratios are formed based on the composition of vehicles merging into the main road and the on-ramp. In the present disclosure, considering the data input requirements of each VSL control strategy and the model construction requirements, the length of the scenario road is set to be 5 km, the length of the on-ramp is 400 m, and the on-ramp confluence is located at 2 km from the starting point of the main road. The VSL signs are disposed at 1000 m, 1200 m, 1400 m, 1600 m and 1800 m from the starting point of the main road, and the VSL signs can be used selectively according to the needs. The data collection points are set at 1100 m, 1300 m, 1500 m, 1700 m and 1900 m from the starting point of the main road for obtaining data information, such as the actual flow volume of the road and the density of the vehicles. Average travel time detectors are disposed at 1 km upstream and 1 km downstream of the bottleneck area (on-ramp confluence point), respectively. Node detectors are set up within 5 km of the whole road section, which are mainly used to measure the service level of the road and the pollutant emission and fuel consumption information. This test system writes an interface function for each detector, and the user can obtain the input data required by the strategy through simple calling of functions.

In particular, five mixed traffic flows with different CAV penetration ratios are formed based on the composition of the vehicles merging on the main road and the on-ramp. The five mixed traffic flows are 100% HDV, 90% HDV-10% CAV, 80% HDV-20% CAV, 70% HDV-30% CAV, and 10% HDV-90% CAV, respectively. The HDVs are the same as the CAVs in length and width. Two types of vehicles are set up, and the two types of vehicles mainly differ in their actual speed compliance to the speed limits shown on the VSL signs. The building codes of the five mixed traffic flows are encapsulated, so that the user can complete the setting of the mixed traffic flows only by selection operation when performing the strategy test.

The VSL strategy is established. For each of the plurality of mixed traffic flows, the speed limit at the upstream of the bottleneck area is calculated based on the VSL strategy. The VSL strategy includes a feedback-based VSL strategy and an optimization-based VSL control strategy.

When determining the speed limit based on the optimization-based VSL control strategy, a cell transmission model is built to calculate a cell density evolution and a cell velocity evolution, so as to obtain an optimal value of an objective function to determine the speed limit.

The feedback-based VSL strategy includes the two-stage cascade feedback control. The first-stage control of the two-stage cascade feedback control is configured to adjust a target flow volume to approach a target density in the bottleneck area, so as to maximize a flow volume in the bottleneck area. A second-stage control of the two-stage cascade feedback control is configured to adjust a ratio of the speed limit to a free flow velocity to regulate an outflow of a variable speed limit control area.

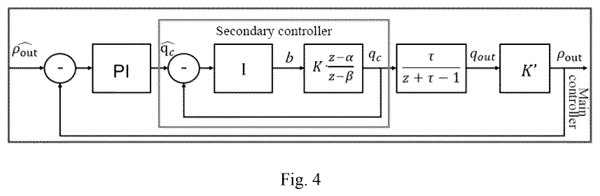

The details are described as follows. The feedback controller for the feedback-based VSL strategy uses a two-stage cascade feedback control structure including a main controller and a secondary controller. The two-stage cascade feedback control structure utilizes multiple feedback variables to divide the process by nested control loops, that is, one for each measurement, whose references are determined by their respective external loops. As shown in FIG. 4, the feedback controller consists of two stages of controllers, namely, a main controller and a secondary controller, respectively. In FIG. 4, b represents the input quantity, ρₒᵤₜ represents the output quantity, q_{c} represents the intermediate output, and [symbol] and [symbol] represents the references, i.e., the predicted values. The secondary loop is affected by the ratio of the speed limit to the free flow velocity given by the secondary controller, which will determine the upstream outflow q_{c}, namely the intermediate output. This upstream outflow is measured and fed back directly in the downstream of the application zone, and is compared to the desired (reference) flow given by the main controller. The primary loop uses the measured density ρₒᵤₜ, namely the output quantity, of the bottleneck area to compare with the set critical density value to maximize the throughput as much as possible. In this embodiment, the main controller is a proportional-integral controller; and the secondary controller is an integral I controller with a transfer function.

The main controller maximizes the flow volume in the bottleneck area by adjusting the target flow volume so that the target flow volume is as close as possible to the target density in the bottleneck area.

The main controller is used to provide a desirable zero steady-state error while maintaining a satisfactory transient response and disturbance rejection. The proportional integral (PI) controller is formulated as

$$\frac{( z )}{{e}_{ρ} ( z )} = \frac{( {K}_{P}^{′} + {K}_{I}^{′} ) z − {K}_{P}^{′}}{z − 1} ,$$

where K′_{P} and K′_{I} are the controller parameters. Similarly, after appropriate changes from the frequency domain to the time domain, the target flow formula expressed as ŷ(k)=ŷ(k−1)+(K′ₗ+K′ₚ)*e_{d}(k)−K′ₚ*e_{d}(k−1) are obtained, where e_{d}(k)=χ−d(k), and χ represents the target density in the bottleneck area. In the two-stage controller, the secondary controller regulates the outflow of the VSL control area by adjusting the ratio of the speed limit. In practical applications, the speed limit obtained from the calculation of the speed limit will be lowered approximately to a multiple of 10 to comply with the constraints of the “Highway Speed limit Signs Specification”. The main controller maximizes the flow volume in the bottleneck area by adjusting the target flow volume so that the target flow volume is as close as possible to the target density in the bottleneck area.

The three controller parameters K_{I}, K′_{P}, and K′_{I} are determined by the two-step method. First, after calculation, the approximate ranges of the three controller parameters are determined, that is, K_{I}∈[0.0001, 0.001], K′_{P}∈[2, 40], and K′_{I}∈[1, 20]. Then, the secondary controller is disconnected from the main controller. The parameter K_{I} of the secondary controller is first optimized, and then after K_{I} is selected, the secondary controller is again connected to the main controller, and parameters K′_{P} and K′_{I} of the main controller are optimized one by one. The optimal values of three controller parameters, K_{I}=0.0002, K′_{P}=38, and K′_{I}=4, are obtained under the condition that control efficiency and the ratio of the speed limit to the free flow velocity are stable.

The target density χ in the bottleneck area is determined from the parameters of the car following model in VISSIM and the traffic fundamental diagram. v_{f} is the free flow velocity of 120 km/h, and L is the average vehicle length of 4.35 m, and the target density is finally determined to be 28 veh/km/lane.

The secondary controller regulates the outflow of the VSL control area by adjusting the ratio of the speed limit to the free flow velocity. The control formula for the secondary controller is expressed as

$$\frac{b ( z )}{{e}_{q} ( z )} = \frac{{K}_{I}}{z - 1} ,$$

where K_{I} is the integral gain of the secondary controller, and e_{q}(z) is the flow control error given per lane. Using the transfer function z, an appropriate transformation is performed from the frequency domain to the time domain to obtain the formula, expressed as b(k)=b(k−1)+K_{I}*e_{q}(k), where b(k) represents the ratio of the speed limits in the current stage, and b(k−1) represents the ratio of the speed limit to the free flow velocity in the previous stage. K_{I} is the control coefficient, e_{q}(k)=ŷ(k)−q_{VSL}(k), ŷ(k) represents the target flow volume, and q_{VSL}(k) is the actual flow volume with variable speed limit.

The process of determining the speed limit based on the optimization-based VSL control strategy is as follows.

(S11) An analytical model is built based on the cell transmission model (CTM). The highway is divided into variable length regions with the cell length of Δx. Time is divided into discrete time steps with duration time of Δt. The length Δxᵢ of each cell follows the constraint of modeling step, and v_{free}Δt≤Δxᵢ, v_{free} represents a free flow velocity. In this embodiment, v_{free} is determined to be 33.3 m/s, Δt is determined to be 6 s, and Δxᵢ is determined to be 200 m. The constraints are intended to ensure that a vehicle traveling at the maximum velocity does not cross multiple cells in a single time step, thereby obtaining accurate data statistics.

(S12) The bottleneck area is modeled, and the free flow velocity is modified to modify a traffic fundamental diagram, so as to adjust the flow volume in the bottleneck area.

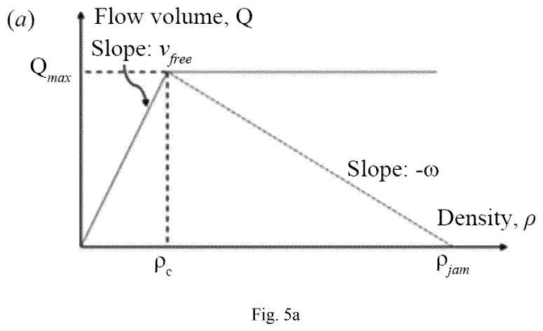

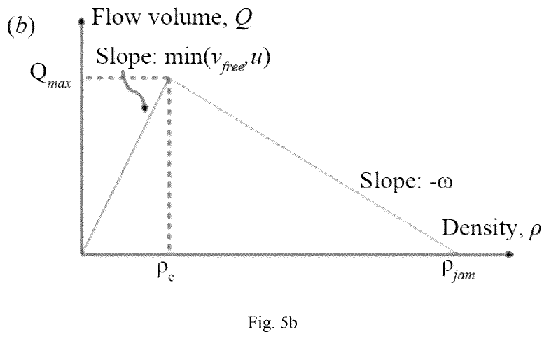

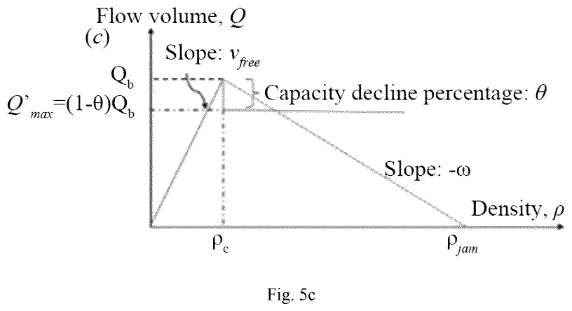

The bottleneck area is modeled, and its capacity decreases after the model is activated, designated as θ. The parameters of the CTM are shown in FIGS. 5a-5c. Since the slopes and the vertices on both sides of the traffic fundamental diagram are explicit parameters, this also facilitates the construction of the traffic fundamental diagram corresponding to a single cell. FIG. 5a shows the traffic fundamental diagram of the cell not controlled by VSL. FIG. 5b shows the traffic fundamental diagram of a cell controlled by VSL (u is the speed limit in m/s, corresponding to the second modification to the traffic fundamental diagram). FIG. 5c shows the traffic fundamental diagram when the capacity of the bottleneck area decreases (θ represents the decreasing proportion of the capacity, corresponding to the first modification to the traffic fundamental diagram).

(S13) The density dynamics and the velocity dynamics are analyzed based on the modified traffic fundamental diagram in step (12) to obtain the cell density and the cell average velocity.

### Density Dynamics

σ(ρ) and δ(ρ) are the demand function and supply function of a single cell, respectively, both of which are functions of cell density ρ. σᵢ(σ) denotes that the cell i needs the space of the downstream cell i+1 to flow with the flow volume of σᵢ(ρ). δᵢ(ρ) denotes that the cell i provides the space for the upstream cell i−1 to flow with the flow volume of δᵢ(ρ).

The demand function and the supply function for cells not controlled by VSL are shown in formulas (2-1) and (2-2), and where λᵢ is the number of lanes.

$${σ}_{i} ( k ) = {v}_{free , i} {ρ}_{i} ( k ) {λ}_{i} ; and \qquad ( 2 - 1 )$$

$${δ}_{i} ( k ) = \{ \begin{matrix}{Q}_{max} , {ρ}_{i} ( k ) \leq {ρ}_{c} \\ {ω}_{i} ( {ρ}_{j a m , i} - {ρ}_{i} ( k ) ) {λ}_{i} , {ρ}_{i} ( k ) > {ρ}_{c}\end{matrix} . \qquad ( 2 - 2 )$$

The demand function and the supply function for the cells controlled by VSL are expressed as:

$${σ}_{i} ( k ) = min \{ {v}_{free , i} , {u}_{i} \} {ρ}_{i} ( k ) {λ}_{i} ; and \qquad ( 2 - 3 )$$

$${δ}_{i} ( k ) = \{ \begin{matrix}{Q}_{max} , {ρ}_{i} ( k ) \leq {ρ}_{c} \\ {ω}_{i} ( {ρ}_{j a m , i} - {ρ}_{i} ( k ) ) {λ}_{i} , {ρ}_{i} ( k ) > {ρ}_{c}\end{matrix} . \qquad ( 2 - 4 )$$

The formula (2-3) represents the role of VSL in the CTM to reduce the inflow volume into the bottleneck area, thereby avoiding disruption of the traffic flow. When the optimal control variable u (speed limit) is less than the free flow velocity, the flow volume demand of the critical cell is uᵢρᵢ(k)λᵢ.

When the upstream of the bottleneck area is at high density, the discharge flow from the upstream cell of the bottleneck area will be reduced, so the demand function of the cell in the bottleneck area is different from that of the other cells, which is calculated by the formula (2-5), but the supply function of the cell in the bottleneck area is the same as that of the other cells, which is calculated by the formula (2-6).

$${σ}_{i , bottleneck} ( k ) = \{ \begin{matrix}{v}_{free , i} {ρ}_{i} ( k ) {λ}_{i} , {ρ}_{i} ( k ) \leq {ρ}_{c} \\ ( 1 − θ ) {Q}_{b} , {ρ}_{i} ( k ) > {ρ}_{c}\end{matrix} ; and \qquad ( 2 - 5 )$$

$${δ}_{i , bottleneck} ( k ) == \{ \begin{matrix}{Q}_{b} , {ρ}_{i} ( k ) \leq {ρ}_{c} \\ {ω}_{i} ( {ρ}_{j a m , i} - {ρ}_{i} ( k ) ) {λ}_{i} , {ρ}_{i} ( k ) > {ρ}_{c}\end{matrix} . \qquad ( 2 - 6 )$$

The formula (2-5) indicates that if the density in the bottleneck area is lower than the critical density, the vehicles can leave the cell at the velocity of v_{free,i}, but once the current density exceeds the critical density, the flow volume of the cell will decrease by a certain ratio.

Once the demand function and the supply function of all the cells are determined, the flow volume of each cell can be determined by the formula (2-7), expressed as:

$${q}_{i} ( k ) = min \{ {σ}_{i} ( k ) , {δ}_{i + 1} ( k ) \} . \qquad ( 2 - 7 )$$

The cell density evolution is then predicted by the formula (2-8), expressed as:

$${ρ}_{i} ( k + 1 ) = {ρ}_{i} ( k ) + \frac{Δ t}{Δ {x}_{i} {λ}_{i}} [ {q}_{i - 1} ( k ) - {q}_{i} ( k ) ] . \qquad ( 2 - 8 )$$

### Velocity Dynamics

The velocity dynamics derived from the traffic fundamental diagram will be described. The velocity dynamics apply to the cells that do not use the VSL strategy. The relationship between the average flow volume and the density are shown in the formula (2-9), expressed as:

$${Q}_{i} [ {ρ}_{i} ( k + 1 ) ] = \{ \begin{matrix}{v}_{free} {ρ}_{i} ( k + 1 ) , & {ρ}_{i} ( k ) \leq {ρ}_{c} \\ {Q}_{max} ( 1 - \frac{{ρ}_{i} ( k + 1 ) - {ρ}_{c , i}}{{ρ}_{jam} - {ρ}_{c , i}} ) , & {ρ}_{i} ( k ) > {ρ}_{c}\end{matrix} . \qquad ( 2 - 9 )$$

In the case of the smooth traffic flow, the formula (2-10) can be derived. That is, the corresponding average velocity of the cell is predicted when its predicted density is known. Since all the parameters in the formula (2-10) can be estimated online or offline, it is more suitable for application in real road scenarios.

$${v}_{i} ( {ρ}_{i} ( k + 1 ) ) == \{ \begin{matrix}{v}_{free} , {ρ}_{i} ( k + 1 ) \leq {ρ}_{c} \\ \frac{{v}_{free} \{ [ {ρ}_{jam} / {ρ}_{i} ( k + 1 ) ] − 1 \}}{[ \frac{{ρ}_{jam}}{{ρ}_{c , i}} − 1 ] , {ρ}_{i} ( k + 1 ) > {ρ}_{c}}\end{matrix} . \qquad ( 2 - 10 )$$

For the cell that uses the optimization-based VSL control strategy, the cell average velocity can be predicted by using the formula (2-11); and uᵢ(k) represents the predicted speed limit of the (k+1)-th step at k-th step, not the speed limit of the k-th step.

$$( 2 - 11 )$$

$${v}_{i} ( k + 1 ) = {r}_{c a v} * {u}_{i} ( k ) + ( 1 - {r}_{c a v} ) * [ {r}_{d e} * ( {u}_{i} ( k ) - 5 ) + {r}_{c o} * {u}_{i} ( k ) + {r}_{a g} * ( {u}_{i} ( k ) + 5 ) ] .$$

In the formula (2-11), r_{cav} represents a proportion of CAVs in the traffic flow; and r_{de}, r_{co}, and r_{ag} represents proportions of defensive drivers, compliant drivers, and aggressive drivers, respectively.

(S14) The proportion of CAVs in the traffic flow and the proportions of different types of HDV drivers in the traffic flow are calculated. Finally, the objective function with the total travel time and the total travel distance as the optimization elements is built and expressed as:

$$( 2 - 12 )$$

$${J}_{1} = T {\sum }_{j = 1}^{{N}_{p} - 1} {\sum }_{i = 1}^{M} {λ}_{i} Δ {x}_{i} [ {α}_{TTT} {ρ}_{i} ( k + j ) - {α}_{TTD} {ρ}_{i} ( k + j ) {v}_{i} ( k + j ) ] .$$

In the formula (2-12), α_{TTT} and α_{TTD} represent the variable weighting coefficients.

The velocity distribution graph for the desired velocity decision is set in VISSIM. Similarly, the building codes for the four compliance scenarios are encapsulated, after the selected compliance scenario is given, the test system can determine the proportion of each type of the HDV drivers based on the current speed limit, thereby making the simulation scenario closer to reality. According to the realistic constraints, the speed limit is 40, 50, 60, 70, 80, 90, 100, or 110 km/h.

TABLE 1
Proportions of each type of HDV drivers when the
compliance and speed limits are determined

| | Low-level compliance | | Medium-level compliance | | High-level compliance | |
|---|---|---|---|---|---|---|
| Speed limit | Defensive | Aggressive | Defensive | Aggressive | Defensive | Aggressive |
| (kph) | driver (%) | driver (%) | driver (%) | driver (%) | driver (%) | driver (%) |
| Vₘᵢₙ = 40 | 30 | 50 | 15 | 40 | 5 | 15 |
| u = 60 | 30 | 50 | 15 | 40 | 5 | 15 |
| u = 70 | 40 | 40 | 20 | 35 | 10 | 10 |
| u = 80 | 40 | 40 | 20 | 35 | 10 | 10 |
| u = 90 | 40 | 40 | 20 | 35 | 10 | 10 |
| u = 100 | 40 | 40 | 20 | 35 | 10 | 10 |
| Vₘₐₓ = 110 | 40 | 40 | 20 | 35 | 10 | 10 |

The types of HDV drivers and the proportion of individual types of the HDV drivers are determined based on the speed limit. The HDV drivers are classified into the defensive drivers, the aggressive drivers, and the compliant drivers based on the travelling speed. The defensive drivers travel at the speed equal to or below (speed limit−5) km/h; the aggressive drivers travel at the speed equal to or above (speed limit+5) km/h; and the compliant drivers travel at the speed within a range of (speed limit±5) km/h.

The HDV compliance only indicates the compliance constraints to the HDV, which represents the proportion of compliant drivers in all HDV drivers in the current traffic condition. HDV compliance includes the low-level compliance (20%), the medium-level compliance (45%), the high-level compliance (80%), and the ideal-level compliance (100%). In other words, the proportion of compliant drivers is 20% under the low-level compliance, the proportion of compliant drivers is 45% under the medium-level compliance, the proportion of compliant drivers is 80% under the high-level compliance, and the proportion of compliant drivers is 100% under the ideal-level compliance. The proportions of the defensive drivers and the aggressive drivers are not set arbitrarily. By modeling and analyzing the data collected over two months on the urban freeway, it is obtained the proportions of each type of drivers under the determined level compliance and the speed limit published on variable message signs (VMS), as shown in Table 1. The proportions of the defensive drivers and the aggressive drivers at the ideal-level compliance (compliance=100%) are 0. Similarly, we encapsulated the building codes for the four compliance scenarios, after the selected compliance scenario is given, the test system can determine the proportion of each type of drivers based on the current speed limit, thereby making the simulation scenario closer to reality.

The experimental design is carried out under the application of the VSL strategy to obtain the indicator data that reflects the traffic capacity. Indicator data reflecting the passing/traffic capacity include vehicles volume, the average travel time of vehicles, vehicle delay, fuel consumption, and pollutant emissions (CO, VOC). These indicators can fully reflect the effect of the application of the VSL strategy in terms of mobility and environmental sustainability, and can be used for data analysis by testers.

The indicator data that reflects the traffic capacity was calculated based on the road scenario in which the driver was located.

In the experiment, five mixed traffic flow scenarios were combined one-to-one with four compliance characteristic scenarios. A total of 40 sets of new test scenarios were designed with the traffic volume of 4800 veh/h on the main road and the traffic volume of 900 veh/h on the on-ramps. The test numbers were 1-40.

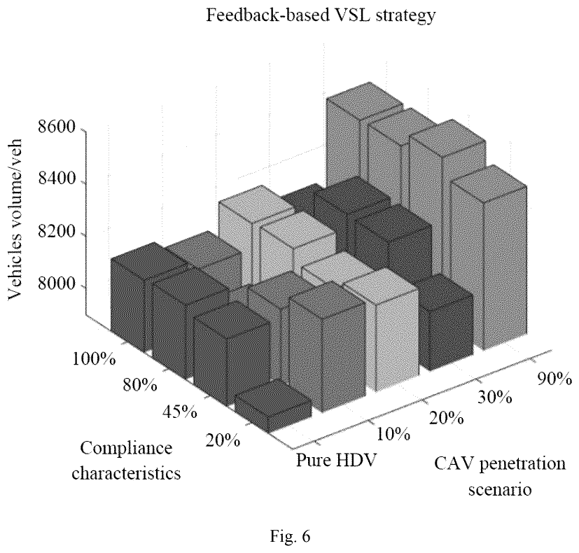

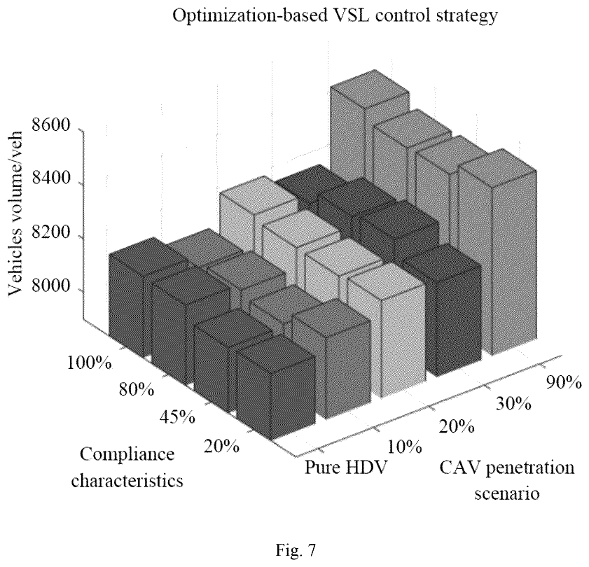

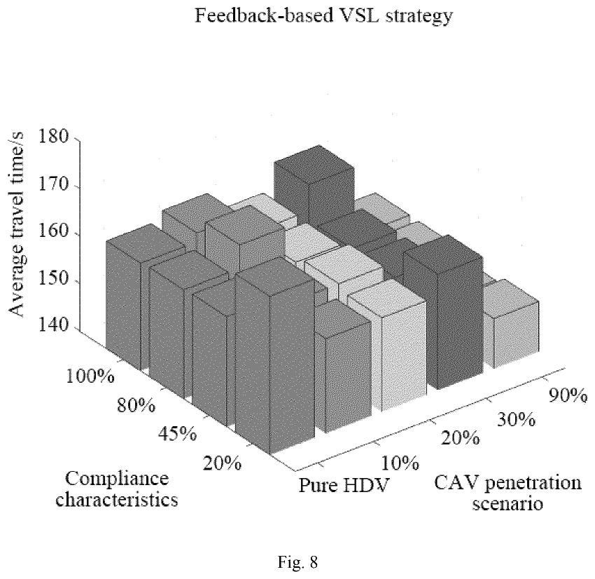

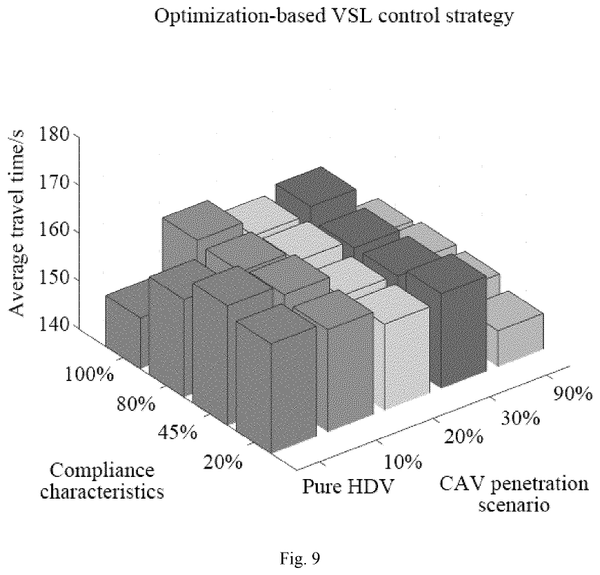

In terms of vehicles volume (FIGS. 6 and 7), vehicles volume was lowest in the scenario with low-level compliance and the scenario with low penetration rate, and with the increase of compliance of HDVs and penetration rates of CAVs, vehicles volume kept increasing. For the feedback-based VSL strategy, in the scenarios with 10%, 20%, and 30% CAV penetration rates, there was no significant increase in traffic capacity. However, in the scenario with 90% CAV penetration rate, the improvement effect was very significant, and in the two hours of simulation, 575 more vehicles passed than the scenarios with the pure HDV and 20% compliance, with the increasing proportion of 7.2%. For the optimization-based VSL control strategy, under the scenarios with 10%, 20%, and 30% CAV penetration rates, there was little difference in vehicles volume as the HDV compliance increased, indicating that the strategy was not suitable for application in these scenarios. However, under 90% CAV penetration rate, there was a significant improvement in vehicles volume, which was about 5%. The average travel time of vehicles within 1 km upstream of the bottleneck area (FIGS. 8 and 9) showed that the lowest point appeared at 90% CAV penetration rate and the ideal-level compliance. Meanwhile, it was found that in the scenario with high CAV penetration rate, the compliance of HDVs produced a very small and almost negligible impact on the overall traffic flow volume. In the scenario with low-level compliance (20%), there was little improvement in the application results, and the feedback-based VSL strategy showed roughly the same improvement at the scenarios with compliances (45%, 80%, and 100%). The optimization-based VSL control strategy showed significant improvement in the scenario with low penetration rate and compliance (100%).

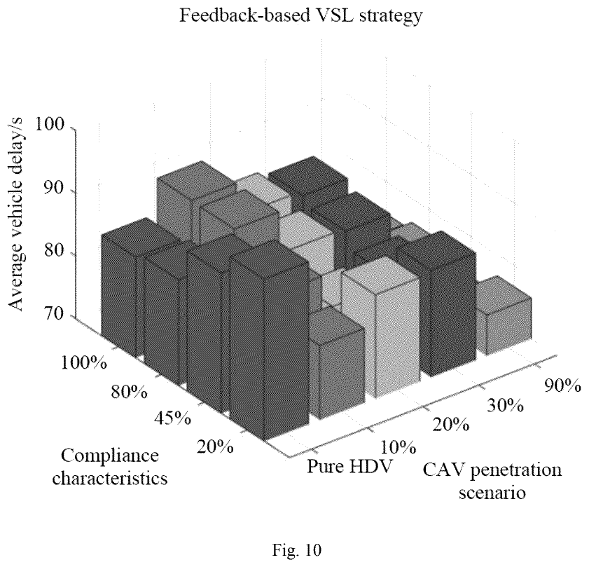

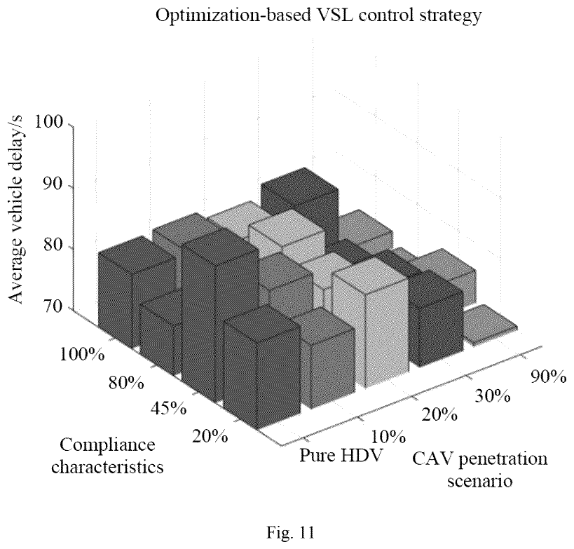

Combining the average travel time with vehicle delays (FIGS. 10 and 11), the feedback-based VSL strategy showed the lowest delays in the scenario with medium-level compliance and high CAV penetration rate; the optimization-based VSL control strategy showed the lowest delays in the scenario with low-level compliance and high CAV penetration rate; and the lowest average travel times were also found in these two experimental scenarios. The feedback-based VSL strategy was not very effective in the scenario with high-level compliance and low CAV penetration rate, and caused a rise in the average travel time due to excessive vehicle delays.

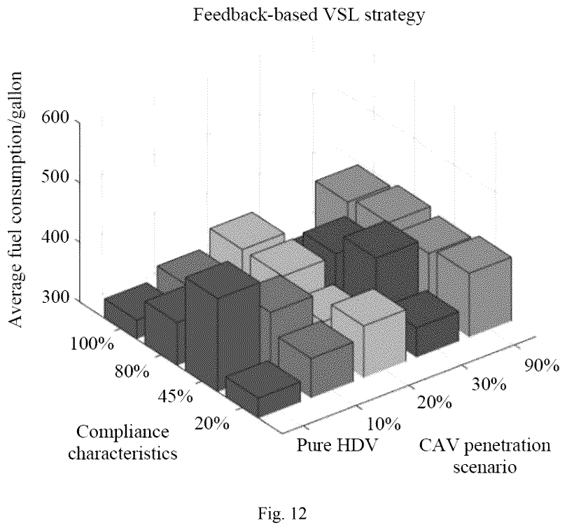

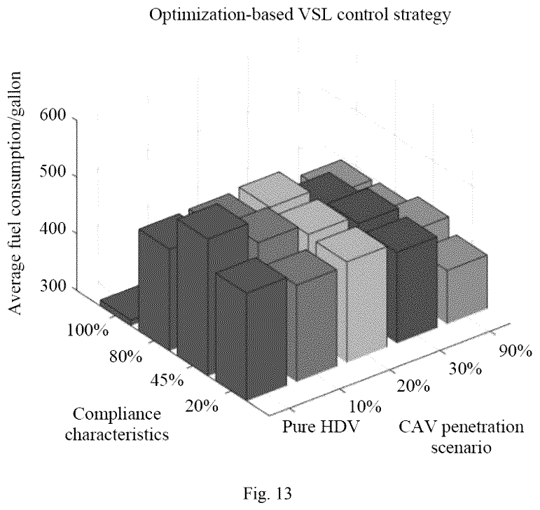

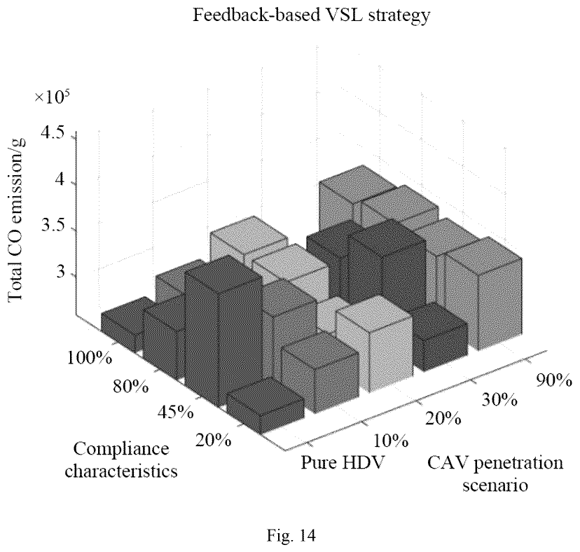

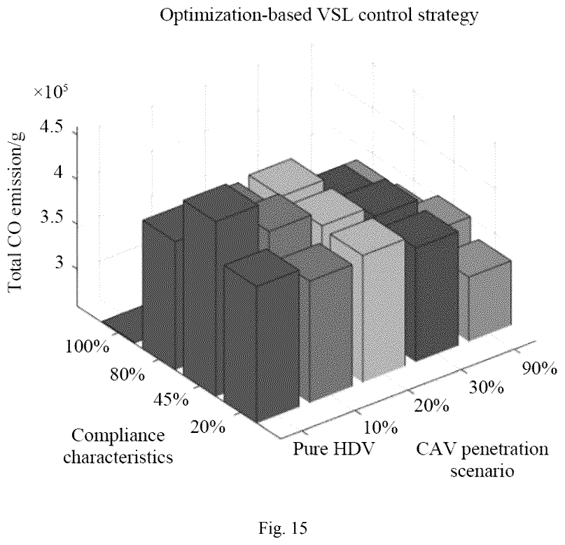

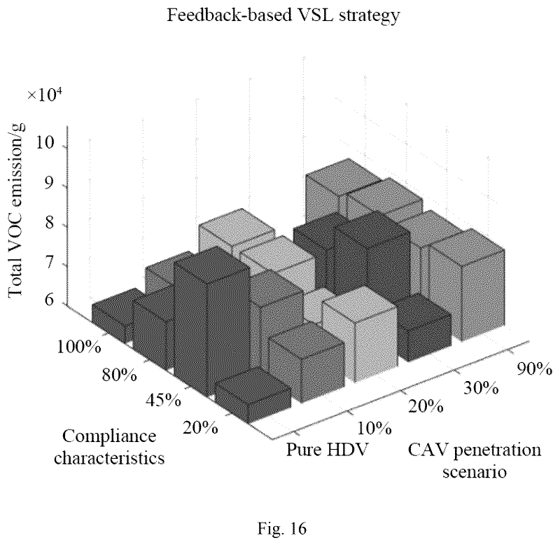

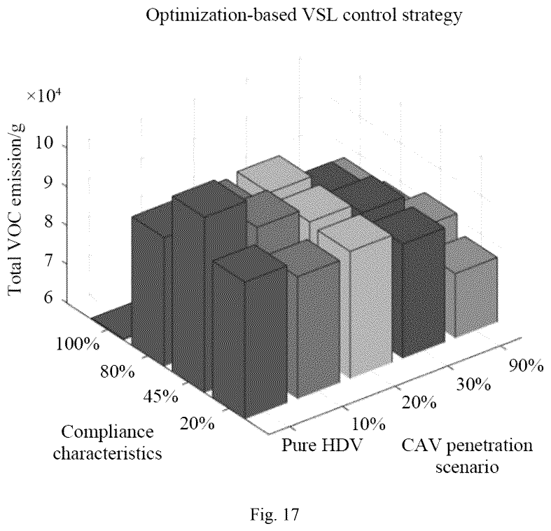

Regarding the average fuel consumption (FIGS. 12 and 13), total CO emissions (FIGS. 14 and 15), and total VOC emissions (FIGS. 16 and 17), the results had the same trend under the two strategies. Overall, under the application of the optimization-based VSL control strategy, both the fuel consumption and the two pollutants (CO and VOC) were at a high level; but the lowest point occurred in scenario with the ideal-level compliance and pure HDV, where the fuel consumption and pollutant emissions were even lower than the effect of the feedback-based VSL strategy. It was worth noting that, in this scenario with the ideal-level compliance and pure HDV, vehicles volume under the optimization-based VSL control strategy is higher than vehicles volume under the feedback-based VSL strategy. The results of the feedback-based VSL strategy were relatively lower, the lowest point appeared in the scenario with the high-level compliance and 10% CAV penetration rate, and the highest point appeared in the scenario with the medium-level compliance and pure HDV; in both scenarios, vehicles volume was 8040 in the former (the scenario with the high-level compliance and 10% CAV penetration rate) and 8159 in the latter (the scenario with the medium-level compliance and pure HDV); the difference in the number of vehicles was about 110, but there was a huge difference of 138.89 gallon in the average fuel consumption. The results of this study once again showed that the application of the optimization-based VSL control strategy should be combined with the current actual application scenarios.

Taking a certain road section as an example, the road section was divided into six cells. The first five cells could selectively use speed limits. The selective use of speed limits could explore the influence of the number of and the location of VSL signs on the application effect of the VSL strategy; and the corresponding detectors were deployed. Among them, the speed limit was limited to 10 km/h. The difference between two consecutive speed limits on the same traffic gantry was not greater than 20 km/h. The refresh time spacing of the speed limits was fixed. As the VSL strategy predicted two steps in the prediction process, it could selectively apply the predicted values in the two steps. If only the predicted value of the first step was applied, the application time length was 10 min; and if the predicted values of the two steps were applied, the application time length of each step was 5 min; and the actual application results found that the application effect of the two-step was better than that of the one step.

The present disclosure also discloses a test system for the VSL considering driver compliance in the mixed traffic flow. With reference to FIG. 8, the test system includes a first building module, a VSL strategy module, a second building module, an acquisition module, and a data processing module. The first building module is configured to build the road scenario. The VSL strategy module is configured to build the VSL strategy. The second building module is configured to establish the HDV compliance. The acquisition module is configured to obtain the CAV penetration rates. The data processing module is configured to calculate the speed limit of the bottleneck area, determine the type of the driver and the proportion of different types of drivers, and obtain the indicator data which reflects the traffic capacity.

The present disclosure also provides a terminal device including a memory, a processor, and a computer program stored in the memory and running on the processor. The processor executes the computer program to implement the test method above.

The present disclosure also provides a non-transitory computer-readable storage medium. A computer program is stored in the non-transitory computer-readable storage medium. The computer program is configured to be executed by a processor to implement the steps of the test method above.

Described above are merely preferred embodiments of the disclosure, which are not intended to limit the disclosure. It should be understood that any modifications and replacements made by those skilled in the art without departing from the spirit of the disclosure should fall within the scope of the disclosure defined by the appended claims.

What is claimed is:

1. A test method for a variable speed limit (VSL) strategy in a mixed traffic flow considering driver compliance, comprising:
(1) building a road scenario based on a road condition of a bottleneck area formed by a main road and an on-ramp, wherein the main road is a three-lane road, and the on-ramp is a single-lane road; and setting a plurality of mixed traffic flows respectively consisting of human-driven vehicles (HDVs) and connected and automated vehicles (CAVs), wherein the plurality of mixed traffic flows vary in CAV penetration rate;
(2) establishing the VSL strategy; and for each of the plurality of mixed traffic flows, calculating a speed limit at an upstream of the bottleneck area based on the VSL strategy;
(3) establishing a HDV compliance; and based on the HDV compliance in combination with the speed limit, classifying HDV drivers in the road scenario, and determining a proportion of the HDV drivers in individual types; and
(4) determining a traffic flow scenario in which the HDV drivers and CAV drivers are located, and testing the traffic flow scenario to obtain indicator data reflecting traffic capacity.

2. The test method of claim 1, wherein the number of the plurality of mixed traffic flows is five, and five mixed traffic flows are 100% HDV, 90% HDV-10% CAV, 80% HDV-20% CAV, 70% HDV-30% CAV, and 10% HDV-90% CAV, respectively; and the HDVs are the same as the CAVs in length and width.

3. The test method of claim 1, wherein the VSL strategy comprises a feedback-based VSL strategy and an optimization-based VSL control strategy.

4. The test method of claim 3, wherein the feedback-based VSL strategy comprises a two-stage cascade feedback control; a first-stage control of the two-stage cascade feedback control is configured to adjust a target flow volume to approach a target density in the bottleneck area, so as to maximize a flow volume in the bottleneck area; and a second-stage control of the two-stage cascade feedback control is configured to adjust a ratio of the speed limit to a free flow velocity to regulate an outflow of a variable speed limit control area.

5. The test method of claim 4, wherein the speed limit is determined based on the optimization-based VSL control strategy through steps of:
(S11) building an analytical model based on a cell transmission model; and dividing a highway into variable length regions with a cell length of Δx, and dividing time into discrete time steps with a duration time of Δt; wherein a length Δxᵢ of each cell follows a constraint of modeling step, and v_{free}Δt≤Δxᵢ, where v_{free} represents the free flow velocity;
(S12) modeling the bottleneck area, and modifying the free flow velocity to modify a traffic fundamental diagram, so as to adjust the flow volume in the bottleneck area; and
(S13) according to a modified traffic fundamental diagram obtained in step (S12), analyzing a density dynamic and a velocity dynamic to obtain a cell density and a cell average velocity; wherein for a cell to which the optimization-based VSL control strategy is applied, the cell average velocity is predicted through the following formula:
$${v}_{i} ( k + 1 ) = {r}_{c a v} * {u}_{i} ( k ) + ( 1 - {r}_{c a v} ) * [ {r}_{d e} * ( {u}_{i} ( k ) - 5 ) + {r}_{c o} * {u}_{i} ( k ) + {r}_{a g} * ( {u}_{i} ( k ) + 5 ) ] ; .$$
wherein uᵢ(k) denotes a speed limit of a (k+1)-th step predicted at a k-th step; r_{cav} denotes a proportion of CAVs in a traffic flow; and r_{de}, r_{co}, and r_{ag} represents proportions of defensive drivers, compliant drivers, and aggressive drivers, respectively.

6. The test method of claim 5, wherein the speed limit is 40, 50, 60, 70, 80, 90, 100 or 110 km/h; and
the HDV drivers are classified into the defensive drivers, the aggressive drivers, and the compliant drivers based on a travelling speed; the defensive drivers travel at a speed equal to or below (the speed limit−5) km/h; the aggressive drivers travel at a speed equal to or above (the speed limit+5) km/h; and the compliant drivers travel at a speed within a range of (the speed limit±5) km/h.

7. The test method of claim 6, wherein the HDV compliance represents a compliance of a HDV in a current traffic condition to a speed limit, and a proportion of the compliant drivers in the HDV drivers; and the HDV compliance comprises a low-level compliance, a medium-level compliance, a high-level compliance, and an ideal-level compliance, wherein the low-level compliance indicates that the proportion of the compliant drivers is 20%, the medium-level compliance indicates that the proportion of the compliant drivers is 45%, the high-level compliance indicates that the proportion of the compliant drivers is 80%, and the ideal-level compliance indicates that the proportion of the compliant drivers is 100%.

8. A system for implementing the test method of claim 1, comprising:
a first building module;
a VSL strategy module;
a second building module;
an acquisition module; and
a data processing module;
wherein the first building module is configured to build the road scenario; the VSL strategy module is configured to build the VSL strategy; the second building module is configured to establish the HDV compliance; the acquisition module is configured to obtain CAV penetration rates; and the data processing module is configured to calculate a speed limit of the bottleneck area, classify the HDV drivers, determine the proportion of the HDV drivers in individual types, and obtain the indicator data reflecting the traffic capacity.

9. A terminal device, comprising:
a memory;
a processor; and
a computer program;
wherein the computer program is stored in the memory, and is configured to be operated on the processor, and the processor is configured to execute the computer program to implement the test method of claim 1.

10. A non-transitory computer-readable storage medium, wherein a computer program is stored on the non-transitory computer-readable storage medium; and
the computer program is configured to be executed by a processor to implement the test method of claim 1.
